(19) United States
(12) Patent Application Publication
(10) Pub. No.: US 2015/0022741 A1
(43) Pub. Date: Jan. 22, 2015

(54) DISPLAY DEVICE, ELECTRONIC DEVICE, AND TOUCH PANEL

(71) Applicant: Sharp Kabushiki Kaisha, Osaka-shi, Osaka (JP)

(72) Inventors: Yusuke Nii, Osaka-shi (JP); Masayuki Kitami, Osaka-shi (JP); Masayoshi Okita, Osaka-shi (JP)

(21) Appl. No.: 14/377,621

(22) PCT Filed: Mar. 25, 2013
(86) PCT No.: PCT/JP2013/002008

§ 371 Date: Aug. 8, 2014

(30) Foreign Application Priority Data
Mar. 30, 2012 (JP) 2012-081305

(51) Int. Cl. H05K 1/18; H04M 1/02; G06F 1/16

(52) U.S. Cl. CPC H05K 1/189; G06F 1/1643; H04M 1/0268; H05K 2201/10151; H05K 2201/10128; H05K 2201/0302
USPC 349/12

(57) ABSTRACT

A plurality of first terminals each being pulled out from a sensor area and a pair of second terminals connected together are provided so as to be lined with one another in a terminal area of a touch panel layer on a cover substrate and, in an FPC, a plurality of first wirings each being configured such that one end thereof is connected to each of the first terminals and the other end thereof extends at an external connection side, a second wiring configured such that one end thereof is connected to one of the second terminals and the other end thereof is grounded, and a third wiring configured such that one end thereof is connected to the other one of the second terminals and the other end thereof extends to reach the external connection side are provided.

### TECHNICAL FIELD

The present disclosure relates to a display device, an electronic device, and a touch panel, and more particularly, relates to a display device including a touch panel and an electronic device which includes the display device and a touch panel.

### BACKGROUND ART

A display device including a touch panel is configured, for example, such that a user touches an icon, etc., displayed on a display screen via the touch panel to enable an operation thereof. In recent years, display devices including a touch panel are built in mobile phones and such mobile phones have drawn attention as multifunctional smart phones. Dedicated electronic devices for mobile use, such as mobile phones, etc., are, in particular, required to have reduced thickness and weight, and therefore, a configuration has been proposed in which some of a plurality of glass substrates that form, for example, a display panel, a touch panel, etc., are shared to reduce the number of glass substrates.

For example, PATENT DOCUMENT 1 describes an electronic device including a touch panel in which touch detection electrodes are provided on the back surface side of a cover substrate that protects a display screen and a liquid crystal display panel provided on the touch panel with a bonding layer interposed therebetween. PATENT DOCUMENT 1 indicates that, in the electronic device, a glass substrate is shared to form both of the cover substrate that protects a surface and the touch panel, and thus, the thickness of the electronic device can be reduced.

### CITATION LIST

### Patent Document

PATENT DOCUMENT 1: International Patent Publication No. WO2010/016174 (FIG. 6)

### SUMMARY OF THE INVENTION

### Technical Problem

The touch panel includes a terminal area in which a plurality of terminals is disposed and, in the terminal area, a flexible printed circuit (FPC) provided for connecting an external circuit, etc., is pressure-bonded with an anisotropic conductive film (ACF) interposed therebetween. In an actual production line, for example, a simple test called impression test is performed in which how much conductive particles included in an ACF are crushed is observed from an opposite surface of the touch panel to a surface thereof to which the FPC is pressure-bonded under a polarizing microscope to confirm electrical connection between each of terminals provided on the touch panel and the corresponding one of terminals provided on the FPC and reliability of connection provided by the ACF in the production line is effectively ensured.

As described in PATENT DOCUMENT 1, in a display device in which a touch panel layer that functions as a touch panel is provided on the back surface side of a cover substrate so as to reduce the thickness of the display device, the cover substrate is a substrate that is viewable to a user, and therefore, a configuration in which a frame-shaped shielding layer is disposed in an outer peripheral portion including a terminal area surrpunding a sensor area in which a touch (or touched) location can be detected has been mainstream for the cover substrate. Therefore, even when an attempt is made to perform the above-described impression test after an FPC is pressure-bonded to the touch panel layer provided at the back surface side of the cover substrate, it is difficult to confirm how much conductive particles included in the ACF are crushed because the shielding layer is provided in the terminal area. Accordingly, it is difficult to ensure reliability of connection provided by the ACF when the FPC is pressure-bonded to the touch panel layer provided on the cover substrate.

In view of the foregoing, the technique disclosed herein has been devised, and an object thereof is to ensure reliability of connection provided by an anisotropic conductive film (ACF) in pressure-bonding a flexible printed circuit (FPC) to a touch panel layer of a cover substrate, even when a shielding film is provided in an outer peripheral portion of a cover substrate.

### Solution to the Problem

In order to achieve the above-described object, according to the present disclosure, a pair of second terminals connected to each other is provided in a terminal area of a touch panel layer on a cover substrate and, on a flexible printed circuit board, a second wiring is provided such that one end thereof is connected to one of the second terminals and the other end thereof is grounded, and a third wiring is provided such that one end thereof is connected to the other one of the second terminals and the other end thereof extends to reach an external connection side.

Specifically, a display device according to one embodiment of the present disclosure includes, a cover substrate on which a frame-shaped shielding layer is provided in an outer peripheral portion thereof, a touch panel layer in which a sensor area is defined inside the shielding layer and a terminal area is defined in a substrate end portion located outside the sensor area, the touch panel layer being provided on the cover substrate, a flexible printed circuit board pressure-bonded to the terminal area of the touch panel layer with an anisotropic conductive film interposed therebetween, and a display panel in which a display area is located so as to overlap the sensor area, the display panel being provided at a touch panel layer side of the cover substrate with a transparent bonding layer interposed therebetween, the touch panel layer includes, in the terminal area, a plurality of first terminals provided so as to be lined with one another, each of the plurality of first terminals being pulled out from the sensor area, and a pair of second terminals provided so as to be lined with the plurality of first terminals, the second terminals being connected to each other, and the flexible printed circuit board includes a plurality of first wirings, each being provided such that one end thereof is connected to each of the first terminals and the other end thereof extends at an external connection side, a second wiring provided such that one end thereof is connected to one of the second terminals and the other end thereof is grounded, and a third wiring provided such that one end thereof is connected to the other one of the second terminals and the other end thereof extends to reach the external connection side.

In the above-described configuration, in the terminal area (of the touch panel layer) of the cover substrate on which the shielding layer is provided, the plurality of first terminals, each being pulled out from the sensor area, and the pair of second terminals connected to each other, is provided so as to lined with one another. Also, the flexible printed circuit board includes the plurality of first wirings, each being provided such that one end thereof is connected to each of the first terminals and the other end thereof extends at an external connection side, the second wiring provided such that one end thereof is connected to one of the second terminals and the other end thereof is grounded, and the third wiring provided such that one end thereof is connected to the other one of the second terminals and the other end thereof extends to reach the external connection side. In this configuration, it may be considered that the flexible printed circuit board is pressure-bonded to the terminal area of the touch panel layer with the anisotropic conductive film interposed therebetween, and thus, the state of electrical connection between each of the first terminals provided in the terminal area of the touch panel layer on the cover substrate and each of the first wirings provided in the flexible printed circuit board approximately matches the state of electrical connection between the pair of the second terminals provided in the terminal area of the touch panel layer on the cover substrate and the second wiring and the third wiring provided in the flexible printed circuit board. In this case, the second wiring (having the other end grounded) provided in the flexible printed circuit board, the pair of the second terminals provided in the terminal area of the touch panel layer on the cover substrate so as to be connected to each other, and the third wiring provided in the flexible printed circuit board are electrically connected to one another in series, if the flexible printed circuit board is correctly pressure-bonded to the terminal area of the touch panel layer, and thus, the state of electrical connection between the pair of the second terminals provided in the terminal area of the touch panel layer on the cover substrate and the second wiring and the third wiring provided in the flexible printed circuit board is confirmed by measuring an electrical resistance between the external connection side of the third wiring provided in the flexible printed circuit board and, for example, a ground electrode provided in a test device, etc. Thus, the state of electrical connection between each of the first terminals provided in the terminal area of the touch panel layer on the cover substrate and each of the first wirings provided in the flexible printed circuit board is also analogized, and therefore, even when the shielding layer is provided in the outer peripheral portion of the cover substrate, reliability of connection provided by the anisotropic conductive film when the flexible printed circuit board is pressure-bonded to the touch panel layer on the cover substrate is ensured in a production line of the display device including the cover substrate (a touch panel) in which the touch panel layer is provided and the display panel by measuring an electrical resistance using the external connection side of the third wiring provided in the flexible printed circuit board.

The flexible printed circuit board may be configured such that a side thereof that is to be pressure-bonded to the terminal area is bifurcated, the second wiring is provided in one of the bifurcated portions, and the third wiring is provided in the other one of the bifurcated portions.

In the above-described configuration, the second wiring is provided in one of the bifurcated portions of the flexible printed circuit board, and the third wiring is provided in the other one of the bifurcated portions, and thus, in both of respective separate pressure-bonded parts of the bifurcated portions of the flexible printed circuit board, the state of electrical connection between each of the first terminals provided in the terminal area of the touch panel layer on the cover substrate and each of the first wirings provided in the flexible printed circuit board is analogized only by measuring an electrical resistance using the external connection side of the third wiring provided in the flexible printed circuit board.

The pair of second terminals may be connected to each other via an outer peripheral wiring provided so as to surround the sensor area.

In the above-described configuration, one of the pair of second terminals is grounded via the second wiring and the pair of the second terminals is connected to each other via an outer peripheral wiring provided so as to surround the sensor area and, for example, destruction of wiring patterns provided in the sensor area due to electrostatic discharge (ESD) is reduced.

The touch panel layer may include an outer peripheral wiring provided so as to surround the sensor area and be grounded.

In the above-described configuration, the touch panel layer includes the outer peripheral wiring provided so as to surround the sensor area and be grounded, and thus, for example, destruction of the wiring patterns provided in the sensor area due to electrostatic discharge is reduced.

The display panel may be a liquid crystal display panel, a backlight may be provided on an opposite side of the display panel to a side thereof on which the cover substrate is provided, and the inner end of the outer peripheral wiring may be located outside the peripheral end of the backlight.

In the above-described configuration, the inner end of the outer peripheral wiring which is to be grounded is located outside the peripheral end of the backlight, and thus, even when incorporation misalignment occurs between the liquid crystal display panel and the backlight, only the outer peripheral wiring protrudes from an incorporated body of the liquid crystal display panel and the backlight and, for example, destruction of the wiring patterns provided in the sensor area due to electrostatic discharge is further reduced.

The touch panel layer may include in the sensor area a plurality of first transparent wiring patterns provided so as to extend in parallel to one another, a plurality of second transparent wiring patterns provided so as to extend in parallel to one another in a direction intersecting with each of the first transparent wiring patterns, and an insulating film provided between the plurality of first transparent wiring patterns and the plurality of second transparent wiring patterns.

In the above-described configuration, the touch panel layer includes in the sensor area the plurality of first transparent wiring patterns provided so as to extend in parallel to one another, the plurality of second transparent wiring patterns provided so as to extend in parallel to one another in a direction intersecting with each of the first transparent wiring patterns, and the insulating film that provides electrical insulation between the plurality of first transparent wiring patterns and the plurality of second transparent wiring patterns, and thus, a projection-type electrostatic capacitive touch panel is specifically formed in the touch panel layer.

An electronic device according to one embodiment of the present disclosure may include any one of the above-described display devices.

In the above-described configuration, in the display device, the pair of second terminals connected to each other is provided in the terminal area (of the touch panel layer) of the cover substrate on which the shielding layer is provided, in the flexible printed circuit board, the second wiring is provided such that one end thereof is connected to one of the second terminals and the other end thereof is grounded, and the third wiring is provided such that one end thereof is connected to the other one of the second terminals and the other end thereof extends to reach the external connection side are provided, and thus, even when the shielding layer is provided in the outer peripheral portion of the cover substrate, reliability of connection provided by the anisotropic conductive film when the flexible printed circuit board is pressure-bonded to the touch panel layer on the cover substrate is ensured in a production line of the electronic device including the display device by measuring an electrical resistance using the external connection side of the third wiring provided in the flexible printed circuit board.

A touch panel according to one embodiment of the present disclosure includes a cover substrate in which a frame-shaped shielding layer is provided in an outer peripheral portion thereof, a touch panel layer in which a sensor area is defined inside the shielding layer and a terminal area is defined in a substrate end portion located outside the sensor area, the touch panel layer being provided on the cover substrate, and a flexible printed circuit board pressure-bonded to the terminal area of the touch panel layer with an anisotropic conductive film interposed therebetween, the touch panel layer includes, in the terminal area, a plurality of first terminals provided so as to be lined with one another, each of the plurality of first terminals being pulled out from the sensor area and a pair of second terminals provided so as to be lined with the plurality of first terminals, the second terminals being connected to each other, and the flexible printed circuit board includes a plurality of first wirings, each being provided such that one end thereof is connected to each of the first terminals and the other end thereof extends at an external connection side, a second wiring provided such that one end thereof is connected to one of the second terminals and the other end thereof is grounded, and a third wiring provided such that one end thereof is connected to the other one of the second terminals and the other end thereof extends to reach the external connection side.

In the above-described configuration, the plurality of first terminals, each being pulled out from the sensor area, and the pair of second terminals connected to each other is provided in the terminal area (of the touch panel layer) of the cover substrate on which the shielding layer is provided so as to be lined with one another. In the flexible printed circuit board, the plurality of first wirings, each being provided such that one end thereof is connected to each of the first terminals and the other end thereof extends at an external connection side, the second wiring provided such that one end thereof is connected to one of the second terminals and the other end thereof is grounded, and the third wiring provided such that one end thereof is connected to the other one of the second terminals and the other end thereof extends to reach the external connection side are provided. In this configuration, the flexible printed circuit board is pressure-bonded to the terminal area of the touch panel layer with the anisotropic conductive film interposed therebetween, and thus, the state of electrical connection between each of the first terminals provided in the terminal area of the touch panel layer on the cover substrate and each of the first wirings provided in the flexible printed circuit board approximately matches the state of electrical connection between the pair of the second terminals provided in the terminal area of the touch panel layer on the cover substrate and the second wiring and the third wiring provided in the flexible printed circuit board. In this case, the second wiring (having the other end grounded) provided in the flexible printed circuit board, the pair of the second terminals provided in the terminal area of the touch panel layer on the cover substrate so as to be connected to each other, and the third wiring provided in the flexible printed circuit board are electrically connected to one another in series, and thus, if the flexible printed circuit board is correctly pressure-bonded to the terminal area of the touch panel layer, the state of electrical connection between the pair of the second terminals provided in the terminal area of the touch panel layer on the cover substrate and the second wiring and the third wiring provided in the flexible printed circuit board is confirmed by measuring an electrical resistance between the external connection side of the third wiring provided in the flexible printed circuit board and, for example, a ground electrode provided in a test device, etc. Thus, the state of electrical connection between each of the first terminals provided in the terminal area of the touch panel layer on the cover substrate and each of the first wirings provided in the flexible printed circuit board is analogized, and therefore, even when the shielding layer is provided in the outer peripheral portion of the cover substrate, reliability of connection provided by the anisotropic conductive film when the flexible printed circuit board is pressure-bonded to the touch panel layer on the cover substrate is ensured in a production line of the touch panel by measuring an electrical resistance using the external connection side of the third wiring provided in the flexible printed circuit board.

### Advantages of the Invention

According to the present disclosure, a pair of second terminals connected to each other is provided in a terminal area of a touch panel layer on a cover substrate and a second wiring provided such that one end thereof is connected to one of the second terminals and the other end thereof is grounded and a third wiring provided such that one end thereof is connected to the other one of the second terminals and the other end thereof extends to reach an external connection side are provided in a flexible printed circuit board, and thus, even when a shielding layer is provided in an outer peripheral portion of the cover substrate, reliability of connection provided by an anisotropic conductive film when the flexible printed circuit board is pressure-bonded to the touch panel layer on the cover substrate can be ensured.

### BRIEF DESCRIPTION OF THE DRAWINGS

FIG. 1 is a perspective view of an electronic device according to a first embodiment.

FIG. 2 is a cross-sectional view of a display device of the electronic device according to the first embodiment.

FIG. 3 is a cross-sectional view of a sensor substrate of the display device according to the first embodiment.

FIG. 4 is a plan view of the sensor substrate according to the first embodiment.

FIG. 5 is a plan view of a touch panel of the display device according to the first embodiment.

FIG. 6 is a plan view of a touch panel according to a second embodiment.

FIG. 7 is a plan view of a first aspect of a touch panel according to a third embodiment.

FIG. 8 is a plan view of a second aspect of the touch panel according to the third embodiment.

FIG. 9 is a plan view of a third aspect of the touch panel according to the third embodiment.

### DESCRIPTION OF EMBODIMENTS

Embodiments of the present disclosure will be hereinafter described in detail with reference to the accompanying drawings. Note that the present disclosure is not limited to the following embodiments.

### First Embodiment

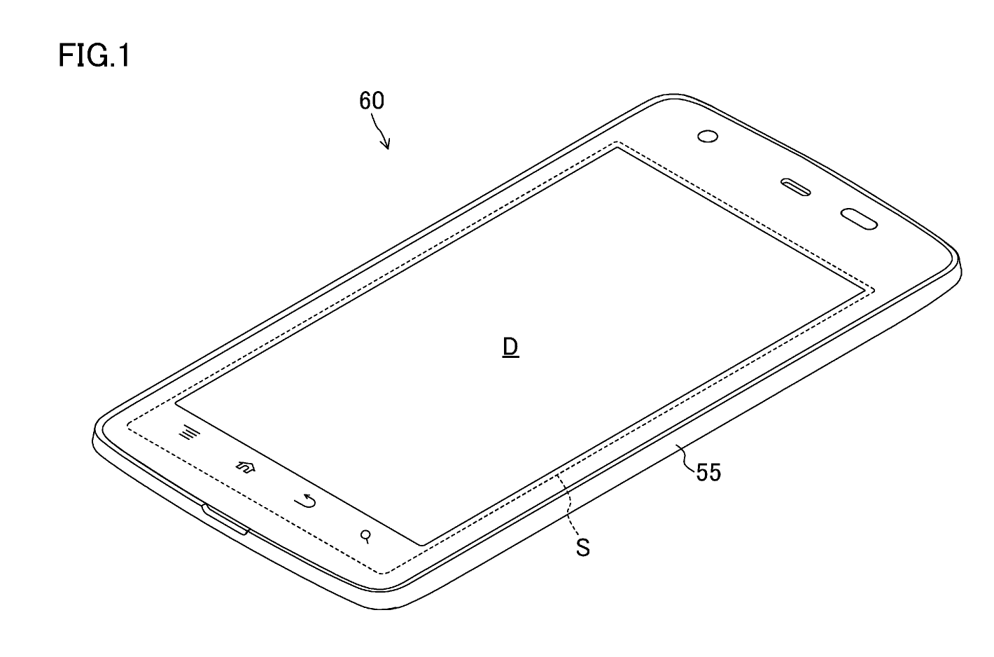

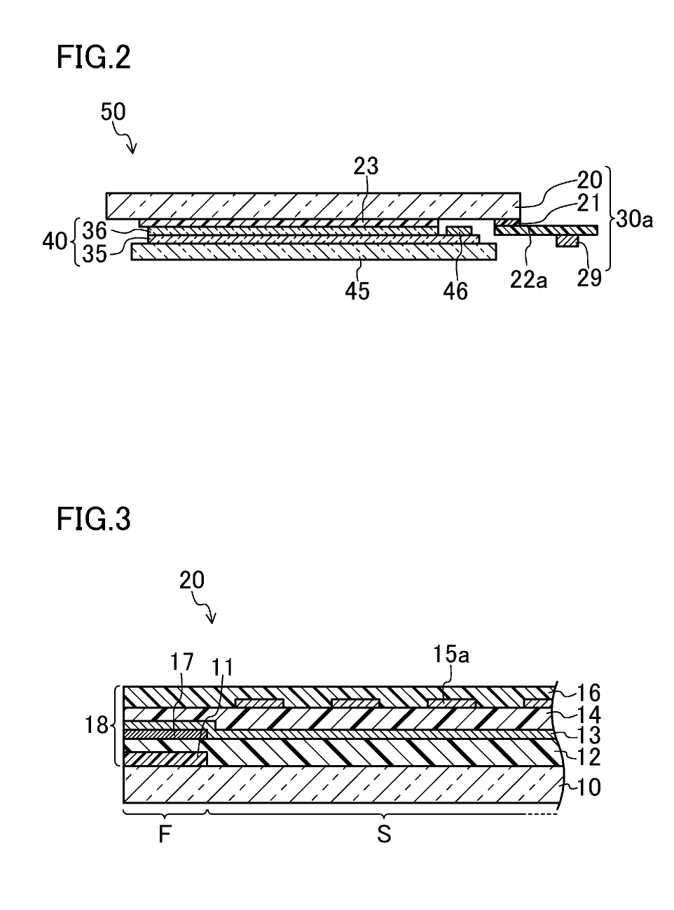

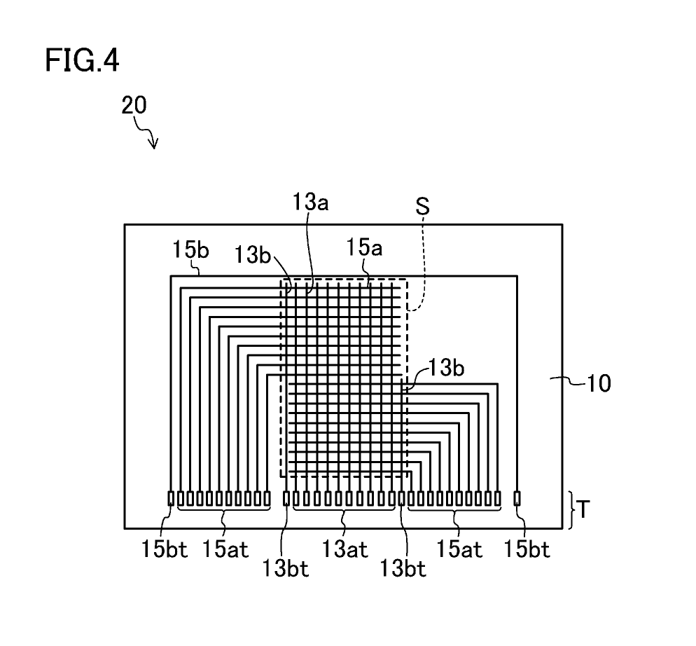

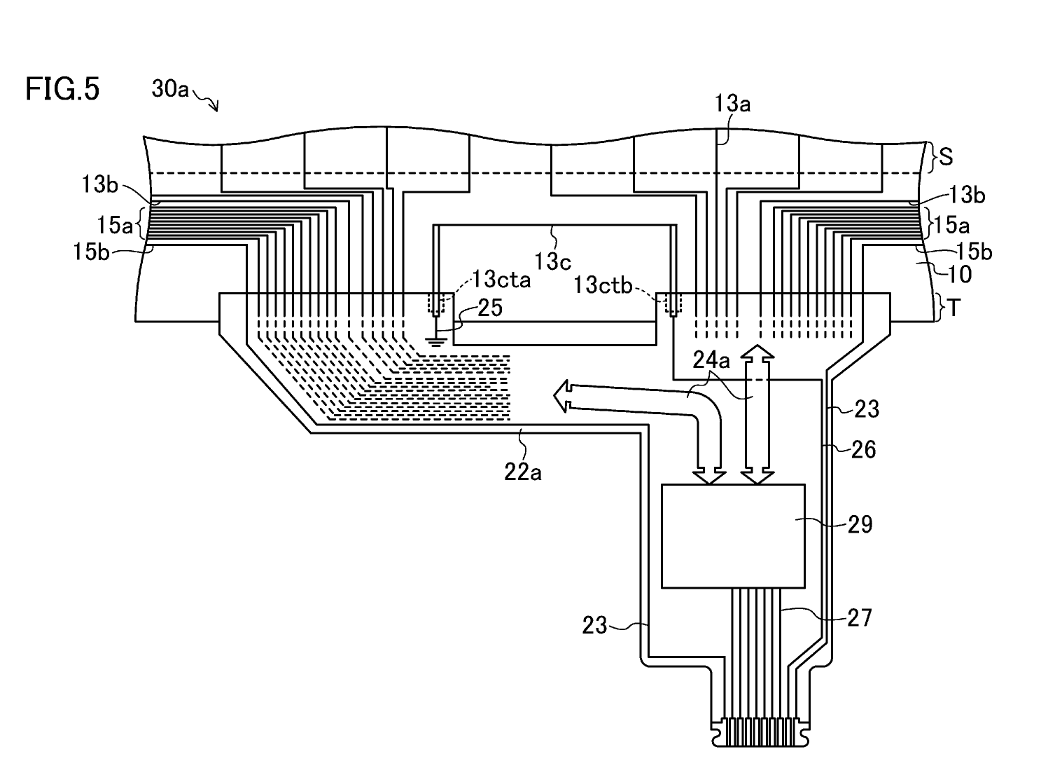

FIGS. 1-5 illustrate a display device, an electronic device, and a touch panel according to a first embodiment of the present disclosure. FIG. 1 is a perspective view of a smart phone 60 according to this embodiment. FIG. 2 is a cross-sectional view of a liquid crystal display device 50 of the smart phone 60. FIG. 3 is a cross-sectional view of a sensor substrate 20 of the liquid crystal display device 50. FIG. 4 is a plan view of the sensor substrate 20. FIG. 5 is a plan view of an end portion of a touch panel 30a of the liquid crystal display device 50.

As illustrated in FIG. 1, the smart phone 60 is an electronic device including the liquid crystal display device 50 (see, for example, FIG. 2) in which a display area D configured to display an image therein is exposed through a rectangular opening formed in a an upper part of a thin case 55 in FIG. 1. In this case, the liquid crystal display device 50 and the smart phone 60 including the liquid crystal display device 50, as illustrated in FIG. 1, the display area D and a sensor area S in which a touch location can be detected are defined such that the sensor area S overlaps an outside portion extending along one of short sides (at the left bottom in the FIG. 1) of the display area D.

As illustrated in FIG. 2, the liquid crystal display device 50 includes the touch panel 30a, a liquid crystal display panel 40 provided under the touch panel 30a in FIG. 2 with a bonding layer 23 interposed therebetween, and a backlight 45 provided under the liquid crystal display panel 40 in FIG. 2.

As illustrated in FIG. 2, the touch panel 30a includes the sensor substrate 20, an FPC 22a pressure-bonded to an end portion (a terminal area T, which will be described later) of the sensor substrate 20 with an ACF 21 interposed therebetween, and a touch panel controller 29 mounted on the FPC 22a.

As illustrated in FIG. 3 and FIG. 4, the sensor substrate 20 includes a cover substrate 10 made of, for example, a glass, a shielding layer 11 provided on the cover substrate 10 so as to have a frame shape, a first planarizing film 12 provided so as to cover the shielding layer 11, a plurality of first transparent wiring patterns 13a provided on the sensor area S of the first planarizing film 12 so as to extend in parallel to one another in the longitudinal direction of the sensor area S in FIG. 4, a pair of ground wiring patterns 13b each being provided on a part of the first planarizing film 12 located outside the sensor area S so as to extend along the corresponding one of the left side and right side of the sensor area S in FIG. 4, an insulating film 14 provided so as to cover each of the first transparent wiring patterns 13a and each of the ground wiring patterns 13b, a plurality of second transparent wiring patterns 15a provided on the sensor area S of the insulating film 14 so as to extend in parallel to one another in a lateral direction of the sensor area S in FIG. 4, an outer peripheral wiring 15b provided on a part of the insulating film 14 located in an outer peripheral portion F located outside the sensor area S so as to surround the sensor area S, and a second planarizing film 16 provided so as to cover each of the second transparent wiring patterns 15a and the outer peripheral wiring 15b. In this case, in the cover substrate 10 (a touch panel layer 18, which will be described later) and the sensor substrate 20, as illustrated in FIG. 3 and FIG. 4, the outer peripheral portion F in which the shielding layer 11 is provided is defined around the sensor area S and a terminal area T is defined along one of the sides of the outer peripheral portion F. Note that, in FIG. 4, the shielding layer 11 provided around the sensor area S is not illustrated.

The shielding layer 11 is made of, for example, a resin material with a black pigment dispersed therein.

The first planarizing film 12, the insulating film 14, and the second planarizing film 16 are made of, for example, a colorless and transparent resin material.

As illustrated in FIG. 4, the plurality of first transparent wiring patterns 13a is each pulled out to the terminal area T to server as a plurality of transmission side first terminals 13at in the terminal area T. As illustrated in FIG. 5, the plurality of first transparent wiring patterns 13a is pulled out to two separate parts of the terminal area T so as to fit the shape of the FPC 22a formed so as to be bifurcated, as will be described later, and accordingly, the plurality of transmission side first terminals 13at is also provided separately in two parts. In FIG. 5, at the right side of a left group of the transmission side first terminals (13at, see, for example, FIG. 4), one of second terminals, i.e., the second terminal 13cta, is provided so as to be lined with each of the transmission side first terminals 13at. Also, in FIG. 5, at the left side of a right group of the transmission side first terminals (13at, see, for example, FIG. 4), the other one of the second terminals, i.e., the second terminal 13ctb, is provided so as to be lined with each of the transmission side first terminals 13at. In this case, as illustrated in FIG. 5, a pair of the second terminals 13cta and 13ctb is connected to each other via an outer peripheral wiring 13c.

As illustrated in FIG. 4, the plurality of second transparent wiring patterns 15a is each pulled out to the right and the left sides of the terminal area T in FIG. 4 to serve as a plurality of reception side first terminals 15at in the terminal area T.

As illustrated in FIG. 4, the pair of ground wiring patterns 13b is each pulled out to the right and left sides of the terminal area T in FIG. 4 to serve as a pair of ground terminals 13bt in the terminal area T.

As illustrated in FIG. 4, the outer wiring 15b is each pulled out to the right and let sides of the terminal area T in FIG. 4 to serve as a pair of ground terminals 15bt in terminal area T. The inner end of the outer wiring 15b extending along the left, upper, and right sides in FIG. 4 are located outside the peripheral ends of a backlight 45. In this case, the width from a peripheral end of the sensor area S to the outer end of the outer peripheral wiring 15b is set to be 2 mm or less.

The first transparent wiring patterns 13a, the ground wiring patterns 13b, the outer peripheral wiring 13c, the second transparent wiring patterns 15a, and the outer peripheral wiring 15b are made of, for example, a transparent conductive film, such as an indium tin oxide (ITO) film, etc. As illustrated in FIG. 3, under the first transparent wiring patterns 13a, the ground wiring patterns 13b, the outer peripheral wiring 13c, the second transparent wiring patterns 15a, and the outer peripheral wiring 15b, a metal layer 17 made of a metal material, such as, for example, aluminum, etc., having a low electrical resistance is stacked in the outer peripheral portion F.

As illustrated in FIG. 3, in the sensor substrate 20, the shielding layer 11, first planarizing film 12, first transparent wiring patterns 13a, the transmission side first terminals 13at, the ground wiring patterns 13b, the ground terminal 13bt, the outer peripheral wiring 13c, the second terminals 13cta and 13ctb, the insulating film 14, the second transparent wiring patterns 15a, the reception side first terminals 15at, the outer peripheral wiring 15b, the ground terminals 15bt, the second planarizing film 16, and the metal layer 17 are provided as the touch panel layer 18.

The ACF 21 is, for example, a film made of thermosetting epoxy resin with conductive particles diffused therein.

The FPC 22a includes, for example, a base film made of polyimide, a pair of copper wiring patterns provided on a surface and the back surface of the base film, and a pair of coverlays made of polyimide provided so as to cover each copper wiring pattern. In this case, as illustrated in FIG. 5, as a specific copper wiring pattern, the FPC 22a includes a ground wiring 23 configured such that one end thereof is connected to each of the ground terminals 15bt (see, for example, FIG. 4) on the sensor substrate 20 and the other end thereof extends to reach an external connection side, a plurality of first wirings 24a each being configured such that one end thereof is connected to each of the transmission side first terminals 13at (see, for example, FIG. 4) and each of the reception side first terminals 15at (see, for example, FIG. 4) on the sensor substrate 20 and the other end thereof extends at the external connection side to reach a touch panel controller 29, a second wiring 25 configured such that one end thereof is connected to the second terminal 13cta on the sensor substrate 20 and the other end thereof is grounded, a third wiring 26 configured such that one end thereof is connected to the second terminal 13ctb on the sensor substrate 20 and the one end thereof extends to reach the external connection side, and a plurality of external connection wirings 27 each being configured such that one end thereof is connected to the touch panel controller 29 and the other end thereof extends to reach the external connection side. As illustrated in FIG. 5, the FPC 22a is formed such that a part thereof that is to be pressure-bonded to the terminal area T of the sensor substrate 20 is bifurcated, the second wiring 25 is provided in one of bifurcated portions thereof (on the left side in FIG. 5) and the third wiring 26 is provided in the other one of the bifurcated portions (on the right side in FIG. 5). Note that, in FIG. 5, since the number of the plurality of first wirings 24a is large, a part thereof located a closer side to the touch panel controller 29 is illustrated by an abstract arrow.

The bonding layer 23 is made of, for example, an optically colorless and transparent double-sided tape, an adhesive, etc.

As illustrated in FIG. 2, the liquid crystal display panel 40 includes, for example, a thin film transistor (TFT) substrate 35 and a color filter (CF) substrate 36 provided so as to face each other, a liquid crystal layer (not illustrated) provided between the TFT substrate 35 and the CF substrate 36, and a sealing member (not illustrated) provided for adhering the TFT substrate 35 and the CF substrate 36 to each other and sealing the liquid crystal layer between the TFT substrate 35 and the CF substrate 36. In this case, as illustrated in FIG. 2, in the liquid crystal display panel 40, a driving large scale integration (LSI) 46 is mounted in a terminal area of the TFT substrate 35 protruding from the CF substrate 36. A polarizing plate is bonded to the surface (for example, the surface on which the CF substrate 36 is located) and back surface (for example, the surface on which the TFT substrate 35 is located) of the liquid crystal display panel 40.

The backlight 45 includes, for example, a thin case, the upper surface of which is open, a flat light-guiding plate provided inside the case, a plate-shaped reflecting sheet provided on a lower surface of the light guiding plate, a plurality of light sources, such as light emitting diodes (LEDs), etc., provided on side surfaces of the light-guiding plate, a half cylindrical reflector provided inside the case so as to surround the plurality of light sources, and an optical sheet, such as a lens sheet, a diffusion sheet, etc., provided on the upper surface of the light-guiding plate.

The smart phone 60 having the above-described configuration is configured such that a predetermined voltage is applied to the liquid crystal layer between the TFT substrate 35 and the CF substrate 36 for each sub-pixel, which is a smallest unit of an image to adjust the transmittance of light being output from the backlight 45 and passing through the liquid crystal display panel 40 and display an image via the touch panel 30a and, when the surface of the cover substrate 10 of the touch panel 30a is touched, the touch panel controller 29 calculates and detects a touch location on the basis of change in electrostatic capacity generated on intersections of the first transparent wiring patterns 13a, the second transparent wiring patterns 15a.

Next, a method for fabricating the liquid crystal display device 50 of the smart phone 60 according to this embodiment will be described. Note that the method for fabricating the liquid crystal display device 50 according to this embodiment includes liquid crystal display panel forming process, touch panel forming process, panel bonding process, and backlight building-in process.

### <Liquid Crystal Display Panel Forming Process>

First, using a known method, a TFT substrate (35) and a CF substrate (36) are separately formed and, for example, after the TFT substrate (35) and the CF substrate (36) are bonded together using a one drop fill (ODF) method, each of respective glass substrates of the TFT substrate (35) and the CF substrate (36) is thinned, thereby forming a liquid crystal display panel 40.

Subsequently, a polarizing plate is bonded to a surface and a back surface of the liquid crystal display panel 40.

Furthermore, after an LSI 46 and a FPC are pressure-bonded to a terminal area of the liquid crystal display panel 40 with an ACF interposed therebetween, how much conductive particles included in the ACF are crushed is observed under a polarizing microscope from an opposite surface of the liquid crystal display panel 40 to a surface thereof to which the LSI 46 and the FPC are pressure-bonded to perform an impression test, thereby ensuring reliability of connection provided by the ACF.

### <Touch Panel Forming Process>

First, using a known method, a shielding layer 11, a first planarizing film 12, a metal layer 17, a first transparent wiring patterns 13a, a transmission side first terminals 13at, a ground wiring patterns 13b, a ground terminals 13bt, an outer peripheral wiring 13c, second terminals 13cta and 13ctb, an insulating film 14, a second transparent wiring patterns 15a, reception side first terminals 15at, an outer peripheral wiring 15b, a ground terminals 15bt, and a second planarizing film 16 are formed over a cover substrate 10 in this order, thereby forming a sensor substrate 20.

Subsequently, a FPC 22a on which a touch panel controller 29 is mounted is pressure-bonded to a terminal area T of the touch panel layer 18 of the sensor substrate 20 with a ACF 21 interposed therebetween, thereby forming a touch panel 30a.

Furthermore, in the touch panel 30a formed in the above-described manner, an electrical resistance between an external connection side of a third wiring 26 provided in the FPC 22a and a ground electrode provided in a test device, etc., is measured, thereby confirming an electrical connection between the pair of second terminals 13cta and 13ctb provided in the terminal area T of the touch panel layer 18 of the touch panel 30a and a second wiring 25 and a third wiring 26 provided in the FPC 22a, and a touch panel pretest is performed to ensure reliability of connection provided by the ACF 21.

### <Panel Bonding Process>

The liquid crystal display panel 40 on which an impression test has been performed in the above-described liquid crystal display panel forming process and the touch panel 30a on which a pretest has been performed in the above-described touch panel forming process are bonded together with an bonding layer 23 interposed therebetween, thereby forming a bonded body.

### <Backlight Incorporation Process>

A backlight 45 is incorporated in the bonded body formed in the above-described panel bonding process, and then, a substantial touch panel test, such as a dynamic operating test of the liquid crystal display panel 40, a touch position accuracy test of the touch panel 30a, etc., is performed.

Thus, a liquid crystal display device 50 according to this embodiment is fabricated. As described above, in each of the touch panel 30a, the liquid crystal display device 50, and the smart phone 60 according to this embodiment, the plurality of transmission side first terminals 13at and the plurality of reception side first terminals 15at each of which is pulled out from the sensor area S and the pair of second terminals 13cta and 13ctb connected to each other are provided so as to be lined with one another in the terminal area T (of the touch panel layer 18) of the cover substrate 10 in which the shielding layer 11 is provided. In the FPC 22a, the plurality of the first wirings 24a each being configured such that one end thereof is connected to each of the transmission side first terminals 13at and each of the reception side first terminals 15at and the other end extends at an external connection side to reach the touch panel controller 29, the second wiring 25 configured such that one end thereof is connected to one of the second terminal 13cta and the other end is grounded, and the third wiring 26 configured such that one end thereof is connected to the second terminal 13ctb and the other end extends to reach the external connection side are provided. In this case, the FPC 22a is pressure-bonded to the terminal area T of the touch panel layer 18 on the cover substrate 10 with the ACF 21 interposed therebetween, and thus, it may be considered that the state of electrical connection between each of the transmission side first terminals 13at and each of the reception side first terminals 15at provided in the terminal area T of the touch panel layer 18 on the cover substrate 10 and each of the first wirings 24a provided in the FPC 22a approximately matches the state of electrical connection between the pair of the second terminals 13cta and 13ctb provided in the terminal area T of the touch panel layer 18 on the cover substrate 10 and the second wiring 25 and the third wiring 26 provided in the FPC 22a. In this case, the second wiring 25 (having the other end grounded) provided in the FPC 22a, the pair of the second terminals 13cta and 13ctb provided in the terminal area T of the touch panel layer 18 on the cover substrate 10 so as to be connected to each other, and the third wiring 26 provided in the FPC 22a are electrically connected to one another in series, if the FPC 22a is correctly pressure-bonded to the terminal area T of the touch panel layer 18, and thus, the state of electrical connection between the pair of the second terminals 13cta and 13ctb provided in the terminal area T of the touch panel layer 18 on the cover substrate 10 and the second wiring 25 and the third wiring 26 provided in the FPC 22a can be confirmed by measuring an electrical resistance between the external connection side of the third wiring 26 provided in the FPC 22a and a ground electrode provided in a test device, etc. Thus, the state of electrical connection between each of the transmission side first terminals 13at and each of the reception side first terminals 15at provided in the terminal area T of the touch panel layer 18 on the cover substrate 10 and each of the first wirings 24a provided in the FPC 22a can be analogized, and therefore, even when the shielding layer 11 is provided in the outer peripheral portion F of the cover substrate 10, reliability of connection provided by the ACF 21 when the FPC 22a is pressure-bonded to the touch panel layer 18 on the cover substrate 10 can be ensured in a production line of the liquid crystal display device 50 including the cover substrate 10 (the touch panel 30a) in which the touch panel layer 18 is provided and the liquid crystal display panel 40 by measuring an electrical resistance using the external connection side of the third wiring 26 provided in the FPC 22a.

Also, in each of the touch panel 30a, the liquid crystal display device 50, and the smart phone 60 according to this embodiment, the second wiring 25 is provided in one of the bifurcated portions of the FPC 22a and the third wiring 26 is provided in the other one of the bifurcated portions thereof, and thus, in both of respective separate pressure-bonded parts of the bifurcated portions of the FPC 22a, the state of electrical connection between each of the transmission side first terminals 13at and each of the reception side first terminals 15at provided in the terminal area T of the touch panel layer 18 on the cover substrate 10 and each of the first wirings 24a provided in the FPC 22a can be analogized only by measuring an electrical resistance using the external connection side of the third wiring 26 provided in the FPC 22a.

In addition, in each of the touch panel 30a, the liquid crystal display device 50, and the smart phone 60 according to this embodiment, the touch panel layer 18 includes the outer peripheral wiring 15b provided so as to surround the sensor area S and to be grounded, and thus, destruction of the first transparent wiring patterns 13a and the second transparent wiring patterns 15a provided in the sensor area S due to electrostatic discharge can be reduced.

Furthermore, in each of the touch panel 30a, the liquid crystal display device 50, and the smart phone 60 according to this embodiment, the inner end of the outer peripheral wiring 15b which is to be grounded is provided so as to be located outside the peripheral end of the backlight 45, and thus, even when incorporation misalignment occurs between the liquid crystal display panel 40 and the backlight 45, only the outer peripheral wiring 15b protrudes from the incorporated body of the liquid crystal display panel 40 and the backlight 45, and destruction of the first transparent wiring patterns 13a and the second transparent wiring patterns 15a in the sensor area S due to electrostatic discharge can be further reduced.

### Second Embodiment

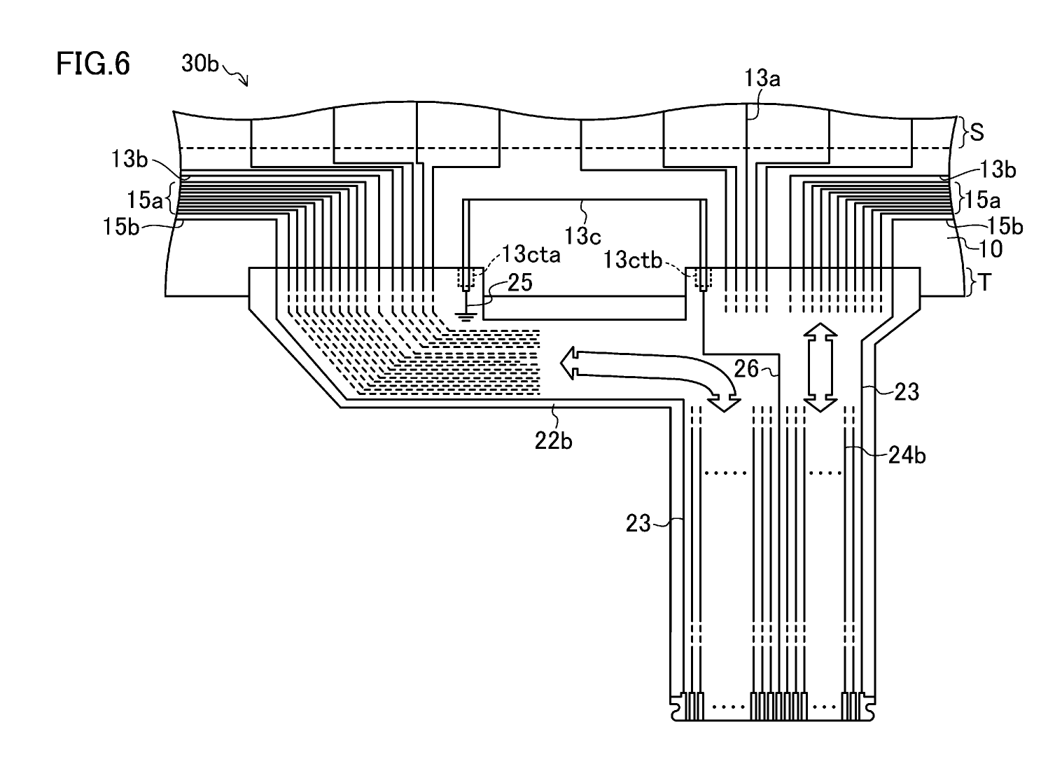

FIG. 6 is a plan view of an end portion of a touch panel 30b according to this embodiment. In each of the following embodiments, those denoted by the same reference numerals in FIGS. 1-5 are the same member, and therefore, the description thereof will be omitted.

In the first embodiment, the touch panel 30a in which the touch panel controller 29 is mounted on the FPC 22a is illustrated, and in this embodiment, a touch panel 30b in which a touch panel controller (29) is not mounted on the FPC 22b is illustrated.

In the touch panel 30b, as illustrated in FIG. 6, the FPC 22b includes a ground wiring 23 configured such that one end thereof is connected to each of ground terminals 15bt (see, for example, FIG. 4) on a sensor substrate 20 and the other end extends to reach an external connection side, a plurality of first wirings 24b each being configured such that one end thereof is connected to each of transmission side first terminals 13at (see, for example, FIG. 4) and each of reception side first terminals 15at (see, for example, FIG. 4) on the sensor substrate 20 and the other end thereof extends to reach the external connection side, a second wiring 25 configured such that one end thereof is connected to a second terminal 13cta on the sensor substrate 20 and the other end thereof is grounded, and a third wiring 26 configured such that one end thereof is connected to a second terminal 13ctb on the sensor substrate 20 and the other end thereof extends to reach the external connection side, and other than that, the touch panel 30b has substantially the same configuration as that of the touch panel 30a according to the first embodiment.

As described above, in the touch panel 30b according to this embodiment, the plurality of transmission side first terminals 13at and the plurality of reception side first terminals 15at each of which is pulled out from the sensor area S and the pair of second terminals 13cta and 13ctb connected to each other are provided so as to be lined with one another in the terminal area T (of the touch panel layer 18) of the cover substrate 10 in which the shielding layer 11 is provided. In the FPC 22b, the plurality of the first wirings 24b each being configured such that one end thereof is connected to each of the transmission side first terminals 13at and each of the reception side first terminals 15at and the other end extends to an external connection side to reach the external connection side, the second wiring 25 configured such that one end thereof is connected to one second terminal 13cta and the other end is grounded, and the third wiring 26 configured such that one end thereof is connected to the second terminal 13ctb and the other end extends to reach the external connection side are provided. In this case, the FPC 22b is pressure-bonded to the terminal area T of the touch panel layer 18 with the ACF 21 interposed therebetween, and thus, it may be considered that the state of electrical connection between each of the transmission side first terminals 13at and each of the reception side first terminals 15at provided in the terminal area T of the touch panel layer 18 on the cover substrate 10 and each of the first wirings 24b provided in the FPC 22b approximately matches the state of electrical connection between the pair of the second terminals 13cta and 13ctb provided in the terminal area T of the touch panel layer 18 on the cover substrate 10 and the second wiring 25 and the third wiring 26 provided in the FPC 22b. In this case, the second wiring 25 (having the other end grounded) provided in the FPC 22b, the pair of the second terminals 13cta and 13ctb provided in the terminal area T of the touch panel layer 18 on the cover substrate 10 so as to be connected to each other, and the third wiring 26 provided in the FPC 22b are electrically connected to one another in series, if the FPC 22b is correctly pressure-bonded to the terminal area T of the touch panel layer 18, and thus, the state of electrical connection between the pair of the second terminals 13cta and 13ctb provided in the terminal area T of the touch panel layer 18 on the cover substrate 10 and the second wiring 25 and the third wiring 26 provided in the FPC 22b can be confirmed by measuring an electrical resistance between the external connection side of the third wiring 26 provided in the FPC 22b and a ground electrode provided in a test device, etc. Thus, the state of electrical connection between each of the transmission side first terminals 13at and each of the reception side first terminals 15at provided in the terminal area T of the touch panel layer 18 on the cover substrate 10 and each of the first wirings 24b provided in the FPC 22b can be analogized, and therefore, even when the shielding layer 11 is provided in the outer peripheral portion F of the cover substrate 10, reliability of connection provided by the ACF 21 when the FPC 22a is pressure-bonded to the touch panel layer 18 on the cover substrate 10 can be ensured in a production line of a liquid crystal display device (50) including the cover substrate 10 (the touch panel 30b) in which the touch panel layer 18 is provided and a liquid crystal display panel (40) by measuring an electrical resistance using the external connection side of the third wiring 26 provided in the FPC 22b.

### Third Embodiment

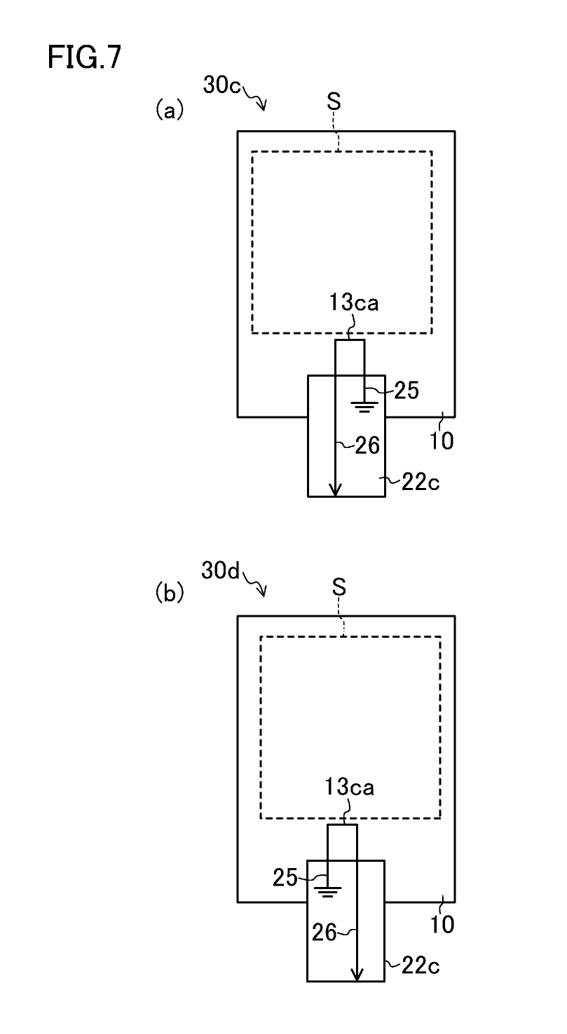

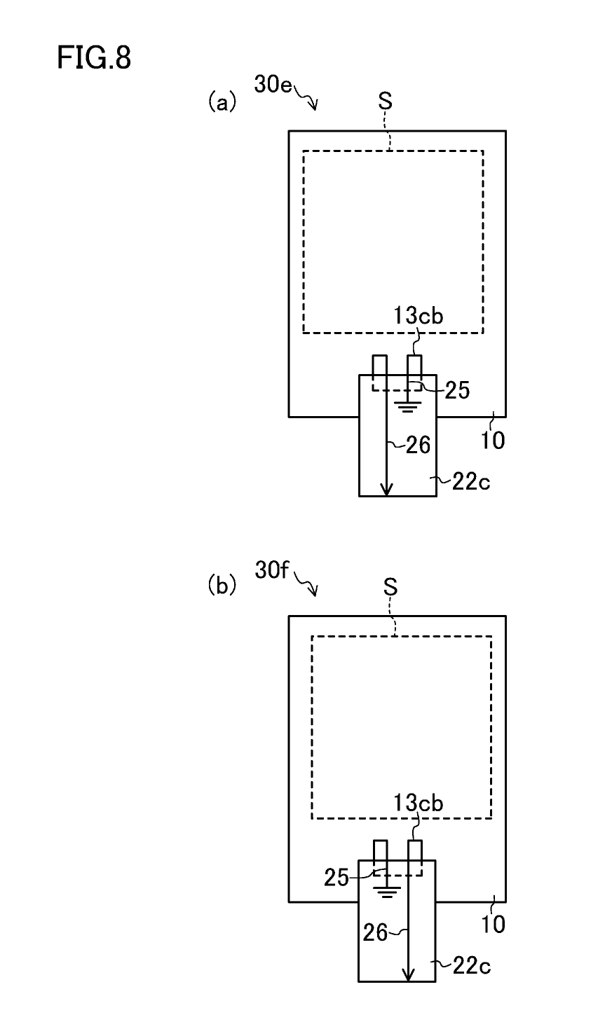

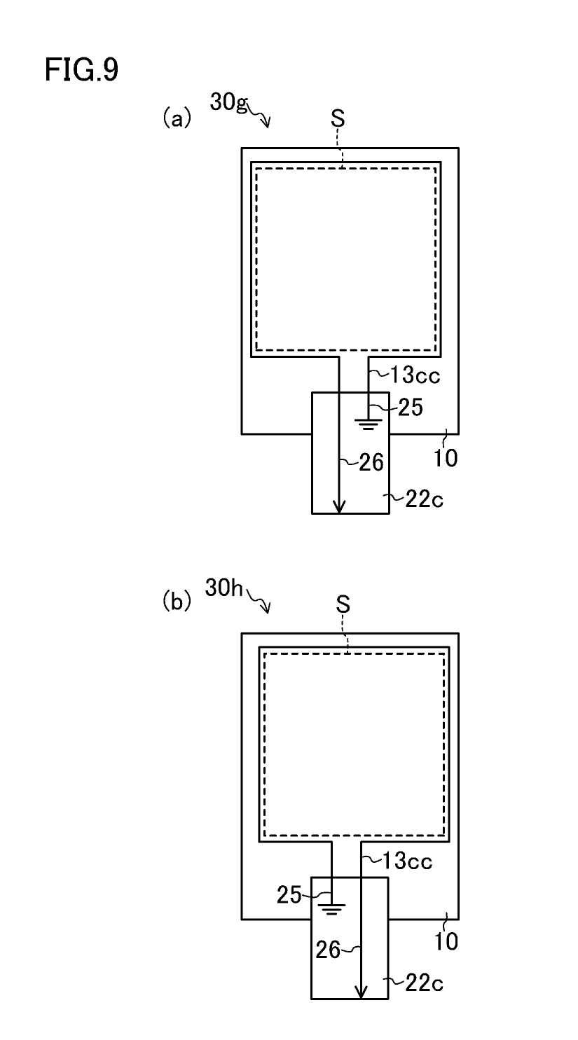

FIG. 7(a) is a plan view of a touch panel 30c according to this embodiment, and FIG. 7(b) is a plan view of a touch panel 30d according to a modified example thereof. FIG. 8(a) is a plan view of a touch panel 30e according to this embodiment, and FIG. 8(b) is a plan view of a touch panel 30f according to a modified example thereof. FIG. 9(a) is a plan view of a touch panel 30g according to this embodiment, and FIG. 9(b) is a plan view of a touch panel 30h according to a modified example thereof.

In the above-described first and second embodiments, the touch panel 30a including the FPC 22a in which a side thereof that is to be pressure-bonded to the terminal area T of the cover substrate 10 is bifurcated and the touch panel 30b including the FPC 22b have been described, and in this embodiment, each of touch panels 30c-30h each including a FPC 22c in which a side thereof that is to be pressure-bonded to the terminal area T of the cover substrate 10 is not bifurcated will be described.

In the touch panel 30c, as illustrated in FIG. 7(a), an outer peripheral wiring 13ca that connects one (13cta) of the second terminals and the other one (13ctb) of the second terminals to each other is provided on a part of the cover substrate 10 located in an area between the upper side of the FPC 22c illustrated as a single portion in FIG. 7(a) and the lower side of a sensor area S in FIG. 7(a), and other than that, the touch panel 30c has substantially the same configuration as that of the touch panel 30a according to the first embodiment or that of the touch panel 30b according to the second embodiment. Note that, as illustrated in FIG. 7(b), the touch panel 30d according to a modified example has a configuration obtained by inverting the configuration of the touch panel 30c right and left.

In the touch panel 30e, as illustrated in FIG. 8(a), an outer peripheral wiring 13cb that connects one (13cta) of the second terminals and the other one (13ctb) of second terminals to each other is provided on a part of the cover substrate 10 located in an area between the upper side of the FPC 22c illustrated as a single portion in FIG. 8(a) and the lower side of a sensor area S in FIG. 8(a) and an area overlapping with the FPC 22c, and other than that, the touch panel 30e has substantially the same configuration as that of the touch panel 30a according to the first embodiment or that of the touch panel 30b according to the second embodiment. Note that, as illustrated in FIG. 8(b), the touch panel 30f according to a modified example has a configuration obtained by inverting the configuration of the touch panel 30e right and left.

In the touch panel 30g, as illustrated in FIG. 9(a), an outer peripheral wiring 13cc that connects one (13cta) of the second terminals and the other one (13ctb) of the second terminals to each other is provided along the surrounding of a sensor area S of the cover substrate 10, and other than that, the touch panel 30g has substantially the same configuration as that of the touch panel 30a according to the first embodiment or that of the touch panel 30b according to the second embodiment. Note that, as illustrated in FIG. 9(b), the touch panel 30h according to a modified example has a configuration obtained by inverting the configuration of the touch panel 30g right and left. In each of the touch panel 30g and the touch panel 30h, one (13cta) of the pair of second terminals is grounded via a second wiring 25 and the pair of the second terminals 13cta and 13ctb are connected to each other via the outer peripheral wiring 13cc provided so as to surround the sensor area S, and thus, the outer peripheral wiring 13cc is grounded and destruction of the first transparent wiring patterns 13a and the second transparent wiring patterns 15a due to electrostatic discharge can be reduced. Also, an inner end of the outer peripheral wiring 13cc extending along the left side, upper side, and right side in FIG. 9(a) and FIG. 9(b) is located outside the peripheral end of a backlight (45). Furthermore, the width from the peripheral end of the sensor area S to the outer end of the outer peripheral wiring 13cc is set to be 2 mm or less.

As described above, in each of the touch panels 30c-30h according to this embodiment, similar to the first embodiment and the second embodiment, the second terminals 13cta and 13ctb each being connected to the terminal area T of the cover substrate 10 via the corresponding one of the outer peripheral wirings 13ca-13cc are provided and, in the FPC 22c, the second wiring 25 configured such that one end thereof is connected to the second terminal 13cta and the other end thereof is grounded and the third wiring 26 configured such that one end thereof is connected to the other second terminal 13ctb and the other end thereof extends to reach the external connection area are provided, and thus, even when the shielding layer 11 is provided in the outer peripheral portion F of the cover substrate 10, reliability of connection provided by the ACF 21 when the FPC 22c is pressure-bonded to the touch panel layer 18 on the cover substrate 10 can be ensured.

Note that, in each of the above-described embodiments, a projection-type electrostatic capacitive touch panel has been described as an example, but the present disclosure is applicable to a touch panel, such as a surface-type electrostatic capacitive touch panel, a resist film type touch panel, etc., which is a different type from the projection-type electrostatic capacitive touch panel.

In each of the above-described embodiments, as a display panel, a liquid crystal display panel has been described as an example, but the present disclosure is applicable to a display panel, such as an organic electro luminescence (EL) display panel, etc., other than the liquid crystal display panel. When the present disclosure is applied to a display device including an organic EL panel, a backlight is not needed, and thus, a device having a further reduced thickness can be realized.

In each of the above-described embodiments, a touch panel including a cover substrate made of glass has been described as an example, but the present disclosure is applicable to a touch panel including a cover substrate made of plastic.

In each of the above-described embodiments, a touch panel in which a plurality of terminals is disposed in a line in a terminal area of a cover substrate has been described as an example, but the present disclosure is applicable to a touch panel in which a plurality of terminals is disposed in a plurality of lines.

In each of the above-described embodiments, a small electronic device for mobile use, such as a mobile phone, etc., has been described as an example, but the present disclosure is applicable to, for example, a large electronic device, such as an electronic black board, etc.

### INDUSTRIAL APPLICABILITY

As described above, according to the present disclosure, even when a shielding layer is provided in an outer peripheral portion of a cover substrate, reliability of connection provided by an ACF when the FPC is pressure-bonded to the touch panel layer on the cover substrate can be ensured, and thus, the present disclosure is useful for producing a mobile electronic device which is required to have a reduced thickness and a reduced weight.

### DESCRIPTION OF REFERENCE CHARACTERS

F Outer peripheral portion
S Sensor area
10 Cover substrate
11 Shielding layer
13a First transparent wiring pattern
13at Transmission side first terminal
13c Outer peripheral wiring
13cta, 13ctb Second terminal
14 Insulating film
15a Second transparent wiring pattern
15at Reception side first terminal
18 Touch panel layer
21 Anisotropic conductive film (ACF)
22a-22c Flexible printed circuit (FPC)
23 Bonding layer
24a, 24b First wiring
25 Second wiring
26 Third wiring
30a-30h Touch panel
40 Liquid crystal display panel
45 Backlight
50 Liquid crystal display device
60 Smart phone (electronic device)

1. A display device, comprising:
a cover substrate on which a frame-shaped shielding layer is provided in an outer peripheral portion thereof;
a touch panel layer in which a sensor area is defined inside the shielding layer and a terminal area is defined in a substrate end portion located outside the sensor area, the touch panel layer being provided on the cover substrate;
a flexible printed circuit board pressure-bonded to the terminal area of the touch panel layer with an anisotropic conductive film interposed therebetween; and
a display panel in which a display area is located so as to overlap the sensor area, the display panel being provided at a touch panel layer side of the cover substrate with a transparent bonding layer interposed therebetween, wherein
the touch panel layer includes, in the terminal area, a plurality of first terminals provided so as to be lined with one another, each of the plurality of first terminals being pulled out from the sensor area, and a pair of second terminals provided so as to be lined with the plurality of first terminals, the second terminals being connected to each other, and
the flexible printed circuit board includes a plurality of first wirings, each being provided such that one end thereof is connected to each of the first terminals and the other end thereof extends at an external connection side, a second wiring provided such that one end thereof is connected to one of the second terminals and the other end thereof is grounded, and a third wiring provided such that one end thereof is connected to the other one of the second terminals and the other end thereof extends to reach the external connection side.

2. The display device of claim 1, wherein
the flexible printed circuit board is configured such that a side thereof that is to be pressure-bonded to the terminal area is bifurcated, the second wiring is provided in one of the bifurcated portions, and the third wiring is provided in the other one of the bifurcated portions.

3. The display device of claim 1, wherein
the pair of second terminals is connected to each other via an outer peripheral wiring provided so as to surround the sensor area.

4. The display device of claim 1, wherein
the touch panel layer includes an outer peripheral wiring provided so as to surround the sensor area and be grounded.

5. The display device of claim 3, wherein
the display panel is a liquid crystal display panel,
a backlight is provided on an opposite side of the display panel to a side thereof on which the cover substrate is provided, and
the inner end of the outer peripheral wiring is located outside the peripheral end of the backlight.

6. The display device of claim 1, wherein
the touch panel layer includes in the sensor area a plurality of first transparent wiring patterns provided so as to extend in parallel to one another, a plurality of second transparent wiring patterns provided so as to extend in parallel to one another in a direction intersecting with each of the first transparent wiring patterns, and an insulating film provided between the plurality of first transparent wiring patterns and the plurality of second transparent wiring patterns.

7. An electronic device, comprising:
any one of the display devices of claim 1.

8. A touch panel, comprising:
a cover substrate on which a frame-shaped shielding layer is provided in an outer peripheral portion thereof;
a touch panel layer in which a sensor area is defined inside the shielding layer and a terminal area is defined in a substrate end portion located outside the sensor area, the touch panel layer being provided on the cover substrate; and
a flexible printed circuit board pressure-bonded to the terminal area of the touch panel layer with an anisotropic conductive film interposed therebetween, wherein
the touch panel layer includes, in the terminal area, a plurality of first terminals provided so as to be lined with one another, each of the plurality of first terminals being pulled out from the sensor area and a pair of second terminals provided so as to be lined with the plurality of first terminals, the second terminals being connected to each other, and
the flexible printed circuit board includes a plurality of first wirings, each being provided such that one end thereof is connected to each of the first terminals and the other end thereof extends at an external connection side, a second wiring provided such that one end thereof is connected to one of the second terminals and the other end thereof is grounded, and a third wiring provided such that one end thereof is connected to the other one of the second terminals and the other end thereof extends to reach the external connection side.
